(19) United States
(12) Patent Application Publication
(10) Pub. No.: US 2014/0103328 A1
(43) Pub. Date: Apr. 17, 2014

(54) ELECTROLUMINESCENT LIGHT EMISSION DEVICE COMPRISING AN OPTICAL LATTICE STRUCTURE AND METHOD FOR MANUFACTURING SAME

(71) Applicant: Fraunhofer-Gesellschaft zur Foerderung der angewandten Forschung e.V., Munich (DE)

(72) Inventors: Richard PFEIFER, Dresden (DE); Karsten FEHSE, Dresden (DE); Uwe VOGEL, Dresden (DE); Karl LEO, Dresden (DE)

(73) Assignee: Fraunhofer-Gesellschaft zur Foerderung der angewandten Forschung e.V., Munich (DE)

(21) Appl. No.: 14/135,654

(22) Filed: Dec. 20, 2013

Related U.S. Application Data
(63) Continuation of application No. PCT/EP2012/062711, filed on Jun. 29, 2012.

(30) Foreign Application Priority Data
Jun. 30, 2011 (EP) 11172129.6

(51) Int. Cl. H01L 51/52

(52) U.S. Cl. CPC H01L 51/5262
USPC 257/40; 438/29

(57) ABSTRACT

A light emission device includes a substrate and a layer arrangement applied onto the substrate. The layer arrangement has a first electrode layer made of a conductive material and a second electrode layer made of a conductive material. At least one light-emitting layer made of an organic material is arranged between the first and second electrode layers. At least one intermediate layer having an optical lattice structure is provided between the light-emitting layer, a first main surface of the intermediate layer facing the light-emitting layer and the first main surface of the intermediate layer being formed to be planar within a tolerance range at least in the region of the optical lattice structure. The intermediate layer is conductive at least in regions between the first and a second main surface thereof.

### CROSS-REFERENCE TO RELATED APPLICATION

This application is a continuation of copending International Application No. PCT/EP2012/062711, filed Jun. 29, 2012, which is incorporated herein by reference in its entirety, and additionally claims priority from European Application No. 11172129.6, filed Jun. 30, 2011, which is also incorporated herein by reference in its entirety.

### BACKGROUND OF THE INVENTION

The present invention relates to an electroluminescent light emission device, such as, for example, an organic light-emitting diode or OLED, comprising an optical lattice or grating structure for improving the coupling out of light, and to a method for manufacturing same.

OLEDs are increasingly employed in the field of illumination and in display technology. The potentially high efficiency, the color space achievable and the thin possible shape of OLEDs contribute particularly to this trend.

The efficiency of an OLED is determined by different factors of which, in highly efficient OLEDs, in particular the efficiency of coupling out light limits the overall efficiency. Whereas light can be generated in a highly efficient manner within the organic layers, only a small portion of the light can be coupled out of the OLED and be made use of as useful light. Due to the high index of refraction of organic layers of about 1.7, a large portion of the light in the organic light-emitting layer remains bound in the form of light modes. In OLEDs on transparent substrates, part of the light enters the substrate and remains bound there in the form of substrate modes and is not coupled out. All in all, about 75% to 80% of the light generated are lost by these effects and additionally by exciting Plasmon modes. Coupling light out of the organic layer in an efficient manner would consequently increase the overall efficiency of OLEDs considerably. Increasing the overall efficiency would be particularly profitable to mobile applications, such as, for example, micro displays based on OLEDs, but also illumination solutions.

### SUMMARY

According to an embodiment, a light emission device may have: a substrate; and a layer arrangement applied onto the substrate having a first electrode layer made of a conductive material, a second electrode layer made of a conductive material, at least one light-emitting layer made of an organic material arranged between the first electrode layer and the second electrode layer and formed as an organic layer stack, and at least one intermediate layer having an optical lattice structure arranged between the organic layer stack and one of the two electrode layers, wherein a first main surface of the intermediate layer faces the organic layer stack and the first main surface of the intermediate layer is formed to be planar within a tolerance range at least in the region of the optical lattice structure, and the intermediate layer is conductive at least in regions between the first main surface and a second main surface, wherein the intermediate layer includes the first and second lattice sub-regions, and the lattice sub-regions has a constant layer thickness.

According to another embodiment, a method for manufacturing a light emission device having a layer arrangement may have the steps of: providing a substrate; arranging a first electrode layer on the substrate; generating a planarized intermediate layer having an optical lattice structure on the electrode layer, the planarized intermediate layer being conductive at least in regions between a first and a second main surface; arranging a light-emitting layer on the intermediate layer; and arranging a second electrode layer on the light-emitting layer, wherein the step of generating the intermediate layer has: applying a first lattice structure base layer on the electrode layer; patterning the first lattice structure base layer so as to obtain first spaced-apart lattice sub-regions and exposed intermediate regions; applying a second lattice structure base layer on the first spaced-apart lattice sub-regions and the exposed intermediate regions; and planarizing at least the second lattice structure base layer so as to obtain the planarized intermediate layer having the optical lattice structure.

According to another embodiment, a light emission device may have: a substrate; and a layer arrangement applied onto the substrate having a first electrode layer made of a conductive material, a second electrode layer made of a conductive material, at least one light-emitting layer made of an organic material arranged between the first electrode layer and the second electrode layer and formed as an organic layer stack, and at least one intermediate layer having an optical lattice structure arranged between the organic layer stack and one of the two electrode layers, wherein a first main surface of the intermediate layer faces the organic layer stack and the first main surface of the intermediate layer is formed to be planar within a tolerance range at least in the region of the optical lattice structure, and the intermediate layer is conductive at least in regions between the first main surface and a second main surface, wherein the intermediate layer includes the first and second lattice sub-regions, and the lattice sub-regions has a constant layer thickness, and wherein the organic layer stack has a hole transport layer, an electron blocking layer, a double emitter layer, a hole blocking layer and/or an electron transport layer.

According to still another embodiment, a light emission device may have: a substrate; and a layer arrangement applied onto the substrate having a first electrode layer made of a conductive material, a second electrode layer made of a conductive material, at least one light-emitting layer made of an organic material arranged between the first electrode layer and the second electrode layer and formed as an organic layer stack, and at least one intermediate layer having an optical lattice structure arranged between the organic layer stack and one of the two electrode layers, wherein a first main surface of the intermediate layer faces the organic layer stack and the first main surface of the intermediate layer is formed to be planar within a tolerance range at least in the region of the optical lattice structure, and the intermediate layer is conductive at least in regions between the first main surface and a second main surface, wherein the intermediate layer includes the first and second lattice sub-regions, and the lattice sub-regions has a constant layer thickness, and wherein the intermediate layer has a silicon material, amorphous silicon material, silicon oxide material and/or metal oxide.

The present invention is based on the finding that the light bound in the organic light-emitting layer may be influenced specifically using a periodically patterned and conductive intermediate layer which is as planar as possible, i.e. a lattice structure as planar as possible, without changing the topology of the planar organic layer or the planar organic layer stack. The patterned intermediate layer as planar as possible including the optical lattice structure is placed between an electrode layer and the organic light-emitting layer such that the intermediate layer including the optical lattice structures, as an optical lattice, is able to couple to the light modes of the light generated in the organic light-emitting layer. The setup of the optical lattice described comprising at least a conductive material allows placing the optical lattice between the electrode layers, i.e. within the optical resonator. This boosts coupling the optical lattice to the light in the organic layers. The surface of the intermediate layer as planar as possible comprising the optical lattice structures allows depositing the organic layers without disturbing the topology, and allows high efficiency when generating light in the organic layer (or the layer stack).

An embodiment of the present invention provides a light emission device comprising a substrate and a layer arrangement applied onto the substrate. The layer arrangement comprises a first electrode layer made of a conductive material, a second electrode layer made of a conductive material, and at least one light-emitting layer made of an organic material, arranged between the first electrode layer and the second electrode layer. In addition, the layer arrangement includes at least one intermediate layer comprising an optical lattice structure arranged between the light-emitting layer and one of the two electrode layers. A first main surface of the intermediate layer is facing the light-emitting layer, the first main surface of the intermediate layer being implemented to be as planar as possible at least in the region of the optical lattice structure, and the intermediate layer being conductive at least in regions between the first main surface and a second main surface thereof. In this embodiment, coupling out of light and, thus, the efficiency of the light-emitting device may be improved by arranging the planar (to the best degree possible) intermediate layer comprising the optical lattice structure in the layer arrangement in direct proximity to the organic layer. Furthermore, it is of advantage that, with such a light emission device, an angular dependency of light emission may be controlled using the intermediate layer, which further increases the efficiency, in particular in the case of applications of limited aperture. The topology of the organic layer is not influenced by the surface, as planar as possible, of the periodically patterned intermediate layer such that the electrical characteristics and, thus, the efficiency are not impaired. However, since, due to manufacturing factors, an ideally plane or planar surface of, for example, the intermediate layer comprising the optical lattice structure frequently cannot be manufactured when using conventional semiconductor manufacturing processes, the maximum allowable, or manufacturing-technologically achievable, unevenness of the first main surface of the intermediate layer is defined by a tolerance range in a range of less than +/−50 nm such that the organic layer may be applied onto an approximately planar surface in which the topology of the organic layer and, thus, the electrical and optical characteristics thereof are not impaired.

In correspondence with an embodiment, the optical lattice structure includes first and second lattice sub-regions which comprise different materials and/or different material characteristics at different indices of refraction. The period length of the optical lattice structure is, at least in regions, adjusted to a wavelength of the light to be emitted by the light-emitting layer such that the period length of the optical lattice structure is in a range of 0.2 to 5.0 times the value of the wavelength of the light to be emitted. It is of advantage here that the lattice structure and, consequently, coupling out of light may be tuned in regions to the light of the light emission device to be emitted in an optimum manner. In order to allow constant lattice characteristics over the width of the optical lattice structure of the intermediate layer, which exemplarily comprises a layer thickness of, at most, up to 1000 nm, the layer thickness in correspondence with another embodiment is as constant as possible over another tolerance range.

Another embodiment of the light emission device comprises an additional conductive charge transport layer between the light-emitting layer and the intermediate layer. This lateral charge transport layer serves for contacting the light-emitting organic layer electrically over the entire area, even when the intermediate layer is conductive only in regions, such as, for example, in the first or second lattice sub-regions. The advantage of the charge transport layer is that the function is ensured even with large period lengths without impairing the electrical characteristics of the light emission device. In correspondence with another embodiment, the layer arrangement includes an additional homogenous conductive distance layer between the intermediate layer and one of the electrode layers which serves for optimizing the position of the optical lattice structure within the resonator i.e. within the layer arrangement. This offers the advantage of further optimizing the efficiency of coupling out light.

In accordance with other embodiments, the layer arrangement may be subdivided into pixels and/or subpixels, wherein the pixels and/or subpixels may be driven selectively, passively or actively by means of an integrated circuit. This advantageous embodiment allows, for example, activating individual pixels of a light emission device comprising several pixels such that the light emission device may be used as a display exhibiting an optimized efficiency of coupling out light. Furthermore, a variable color representation is made possible by the subpixels of different colors.

In accordance with another embodiment, the light emission device may comprise two intermediate layers each provided with an optical lattice structure. Here, the second intermediate layer is arranged between the first intermediate layer and the first electrode layer, wherein the first main surface of the intermediate layer which faces the light-emitting layer is implemented each to be planar within the tolerance range at least in the region of the optical lattice structure. Additionally, the first and second intermediate layers are conductive at least in regions between the first main surfaces and second main surfaces thereof. It is of advantage here that coupling out of light may be optimized for several colors by the additional intermediate layer and that the light may specifically be coupled out in several directions at the same time.

Another embodiment of the present invention relates to a method for manufacturing a light emission device comprising a layer arrangement. The method includes the following steps: providing a substrate and arranging a first electrode layer on the substrate, generating a planarized intermediate layer comprising an optical lattice structure, on the first electrode layer, the planarized intermediate layer being conductive at least in regions between a first and a second main surface thereof, arranging a light-emitting layer on the intermediate layer and arranging a second electrode layer on the light-emitting layer. The advantage of this method for manufacturing is that a light emission device, optimized with regard to efficient coupling out of light, comprising an optical lattice structure may be manufactured in a process-secure and cheap manner, wherein the electrical characteristics are not impaired due to planarization.

In accordance with another embodiment, the planarized intermediate layer may be manufactured using the following steps: applying a first lattice structure base layer onto the electrode layer, patterning the first lattice structure base layer to obtain first spaced-apart lattice sub-regions and exposed intermediate regions, applying a second lattice structure base layer onto the first spaced-apart lattice sub-regions and the exposed intermediate regions, planarizing the second lattice structure base layer to obtain the planarized intermediate layer comprising the optical lattice structure. Another embodiment of the method for manufacturing a light emission device additionally includes the step of generating another planarized intermediate layer comprising another optical lattice structure on the planarized intermediate layer. The planarized further intermediate layer is conductive at least in regions between a first and a second main surface.

Subsequently, critical characteristics of conventional OLED structures will be discussed using further known documents, wherein additionally the findings and inventive conclusions of the inventors when considering the object on which the present invention is based will be emphasized.

Different approaches have been examined for solving the problem of coupling out light, wherein three different OLED setup approaches are to be differentiated. On the one hand, the light may be emitted directly through a transparent top electrode to the side facing away from the substrate. Such OLEDs are called top-emitting OLEDs or TOLEDs. Here, an opaque substrate is made use of. When using transparent substrates, the light may also be emitted through the substrate itself. The OLEDs emitting through the substrate are called bottom-emitting (or substrate-emitting) OLEDs or BOLEDs. Transparent substrate contacts and opaque top contacts are made use of here. Additionally, in so-called transparent OLEDs, the light may be emitted on the substrate side and the top contact side using a transparent substrate and a transparent top contact. In BOLEDs, the coupling-out efficiency may be improved by coupling out the light bound in the substrate, for example by patterning [2] or roughening [3] the substrate. Additional approaches here are introducing scattering layers [4] or layers of low an index of refraction [5].

Of particular importance is using periodically patterned layers to specifically influence the propagation of light by diffraction of light. Optical lattices made of materials of different indices of refraction, the period length of which is in the order of magnitude of the wavelength of the light emitted, may direct the light specifically to the outside. Here, the angular distribution of the light emitted can be influenced such that coupling out of light is optimized. This is of particular importance in certain applications where only that part of the light is made use of which is emitted in a certain angular range. An example of this is a micro display in which the light generated by the OLED is directed through further optical elements which comprise only a limited aperture. A specific influence of the angular dependence of the radiation emitted here may also improve the system efficiency of such applications considerably.

In order to be able to effectively couple out the light bound in the organic modes, it has, for example, been attempted in OLEDs or BOLEDs to place periodic patterns in direct proximity to the organic layers. The present inventors have found out that integrating an optical lattice structure between the electrodes is difficult since the organic materials limit the process of lattice manufacturing due to their sensitivity to, for example, temperature. In existing solutions, this problem is to be bypassed by at first performing the process of patterning the lattice and then depositing the organic layers. A conventional embodiment here is patterning the substrate or an intermediate layer in order to then deposit the substrate electrode [7, 8, 9]. The electrode and, thus, also the organic layer consequently exhibit the same topology as the patterned substrate. Further embodiments comprise post-patterning of the electrode deposited on the substrate [US 2004/0012328 A1] or depositing periodic patterns on the electrode [US 2010/0283068 A1). In these embodiments, the topology of the electrode is transferred onto the organic layer.

With regard to those solution variations where the organic layer is deposited onto a patterned and, thus, non-planar surface, it has been found out and recognized by the present inventors that coupling out of light is not ideal. The reason for this is that the layer thickness of the organic layer is not constant over the entire illumination area, as a direct consequence of patterning. Patterning metallic electrodes results in the excitation of plasmon modes which in turn may result in light absorption and, consequently, in a deterioration in the coupling out of light. Furthermore, it has been found out that the electrical characteristics of the OLED are impaired by this. The edges and inclinations caused by patterning may exemplarily result in short-circuits between electrodes and in an increase in leakage currents [11].

Further current solutions for BOLEDs on transparent substrates comprising (semi-) transparent substrate electrodes are placing the lattice layers between substrate and electrode [US 2009/0015142 A1, US 2006/0071233 A1, US 2008/0284320 A1, U.S. Pat. No. 7,696,687 B2, US 2007/0241326 A1]. Here, the electrical characteristics of the OLED are not impaired to the same extent as in the above three solutions. However, it has been found out and the present inventors have recognized that the coupling out of light is not ideal due to the remote position of the optical lattice from the organic layer, namely between electrode and substrate.

### BRIEF DESCRIPTION OF THE DRAWINGS

Embodiments of the invention will be detailed subsequently referring to the appended drawings, in which:

FIG. 1 is a schematic sectional illustration of a light emission device comprising a layer arrangement comprising an intermediate layer having an optical lattice structure, in accordance with an embodiment;

FIGS. 2a-2c are schematic illustrations of a light emission device, and illustrations of corresponding parameters of optimization;

FIG. 3 is a schematic sectional illustration of a light emission device comprising a layer arrangement comprising an intermediate layer having an optical lattice structure and a lateral charge transport layer, in accordance with another embodiment;

FIG. 4 is a schematic sectional illustration of a light emission device comprising a layer arrangement comprising an intermediate layer having an optical lattice structure and a distance layer, in accordance with another embodiment;

FIG. 5 is a schematic sectional illustration of a light emission device comprising a layer arrangement comprising two intermediate layers having optical lattice structures, lateral charge transport layers and further distance layers, in accordance with another embodiment; and

FIGS. 6a-6e show a method for manufacturing a light emission device using five process sub-steps, in accordance with an embodiment.

### DETAILED DESCRIPTION OF THE INVENTION

Before discussing the present invention below in greater detail using drawings, it is pointed out that identical elements and structures for elements and structures having the same function or the same effect, in the different figures, are provided with same reference numerals such that the description presented in the different embodiments of the elements and structures provided with same reference numerals may be interchanged and mutually applied.

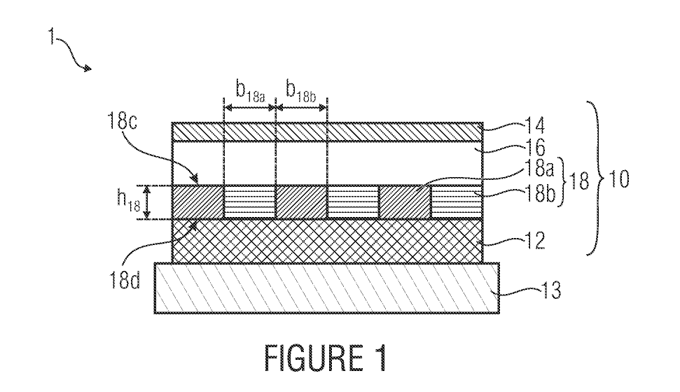

A planar electroluminescent light emission device 1 in accordance with a first embodiment of the present invention will be described making reference to FIG. 1. In particular, FIG. 1 shows a layer arrangement 10 of the light emission device 1 applied onto a substrate 13. The layer arrangement 10 comprises a first electrode layer 12 and a second electrode layer 14 which both comprise a conductive material such as, for example, aluminum. A light-emitting layer 16 made of an organic material is arranged between the two electrode layers 12 and 14. It is pointed out that such light-emitting layers may frequently be implemented as layer stacks comprising several individual organic layers. An intermediate layer 18 comprising an optical lattice structure is provided between the first electrode layer 12 and the light-emitting layer 16. A first main surface 18c of the intermediate layer 18, which is as planar as possible, is facing the light-emitting layer 16, whereas a second main surface 18d faces the first electrode layer 12. The intermediate layer 18 comprises an optical lattice structure which in this embodiment is implemented using first lattice sub-regions 18a and second lattice sub-regions 18b. The lattice sub-region 18a and 18b exhibit different indices of refraction and are arranged periodically at a period length which corresponds to the sum of the lateral widths b₁₈ₐ and b_{18b} of the lattice sub-regions 18a and 18b. In this embodiment, the lateral widths b₁₈ₐ and b_{18b} of the lattice sub-regions 18a and 18b are equal, wherein the lattice sub-regions 18a and 18b may also exhibit different widths b₁₈ₐ and b_{18b}, in order for optical characteristics of the intermediate layer 18 to be adjustable or selectable in dependence on the lattice structure, in correspondence with the field of application. The intermediate layer 18 and, thus, also the lattice sub-regions 18a and 18b in this embodiment are of a constant layer thickness h₁₈ between the first and second main surfaces 18c and 18d. The substrate 13 on which the electrode layer 12 and, thus, the layer arrangement 10 are arranged exemplarily comprises opaque silicon or transparent glass. The mode of functioning of this embodiment will be discussed below in greater detail.

Light emission is excited to occur in the organic layer 16 by means of an electrical current between the first electrode layer 12 and the second electrode layer 14 and through the light-emitting organic layer 16. In order to be able to couple out the light emitted efficiently and avoid losses in substrate or organic modes, the light emitted or light modes in the intermediate layer 18 is/are directed or oriented by means of the optical lattice structure. This orientation of light modes takes place due to diffraction at the optical lattice structure or at the lattice sub-regions 18a and 18b which exemplarily exhibit different indices of refraction. In order to form a gradient of the indices of refraction, the first and second lattice sub-regions 18a and 18b may exhibit different material characteristics and/or different materials. A current flowing between the first electrode layer 12 and the second electrode layer 14 through the light-emitting layer 16 is made possible by implementing the intermediate layer 18 to be conductive at least in regions between the first and second main surfaces 18c and 18d or implementing at least one of the lattice sub-regions 18a and/or 18b to be made of a conductive material.

In order not to impair the electrical characteristics of the organic light-emitting layer 16, the light-emitting layer 16 is arranged on a surface which in the ideal case is planar, namely the first main surface 18c. Since an ideal planar surface is impossible to generate due to manufacturing reasons, a tolerance range is determined which, on the one hand, fulfils the requirements with regard to planarity of the organic layer 16 and, on the other hand, can be produced from a manufacturing point of view. The tolerance range determined in this embodiment states unevenness of the first main surface 18c to be in a range of less than +/−50 nm (or +/−20 nm), i.e. the maximum deviation of a point of the first main surface 18c in the region of the optical lattice structure from the ideal planar level is 50 nm in a first direction (direction of light-emitting layer 16) or in a second, opposite direction (direction of the first electrode layer 12). It is pointed out here that greater unevenness outside the region of the optical lattice structure of the intermediate layer 18 or outside the light-emitting regions of the organic layer 16 may be allowable since evenness in these regions has a negligible influence on the resulting electrical and optical characteristics. The tolerance value of +/−50 nm is established by the fact that typically the electrical characteristics of the organic light-emitting layer 16 are not impaired significantly by unevenness within this tolerance range, and that typical planarization methods are able to generate surfaces with a maximum surface unevenness or roughness of less than +/−50 nm. Underlying the surface unevenness is the fact that surface unevenness caused by the processes or roughness remains after the grinding process, in planarization methods such as, for example, chemical-mechanical polishing (CMP). When planarizing, one of the two lattice sub-regions 18a or 18b serves as a stop layer or etch stop layer. All the more, when planarizing the intermediate layer 18 which comprises the first and second lattice sub-regions 18a and 18b, so-called steps will result, since the lattice sub-regions 18a and 18b exhibit different material characteristics which have an effect on planarization. It is to be pointed out here that different types of organic layers pose different requirements to the surface unevenness of the background so that in further embodiments the main surface 18c is planar within a tolerance range of +/−20 nm, +/−10 nm or +/−5 nm.

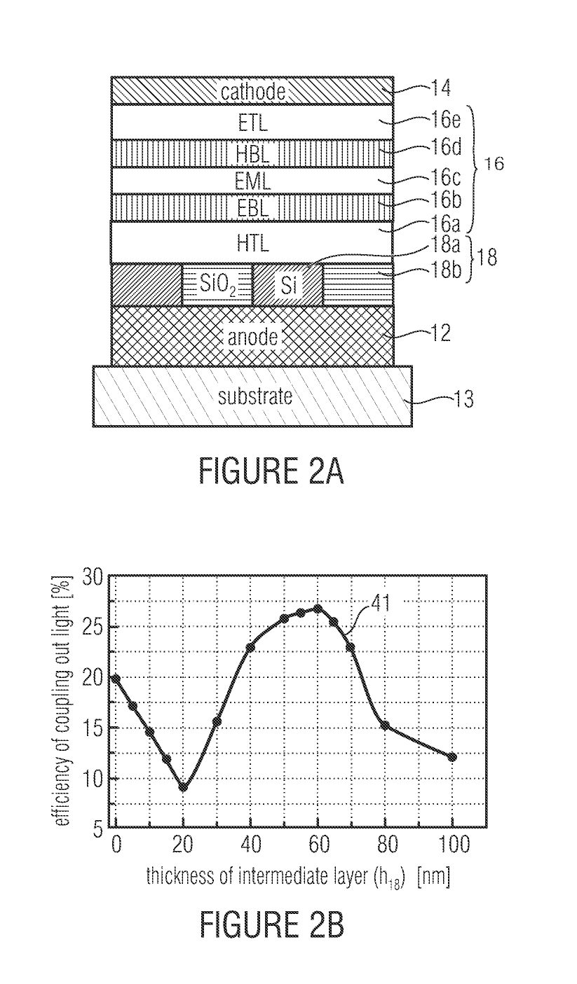

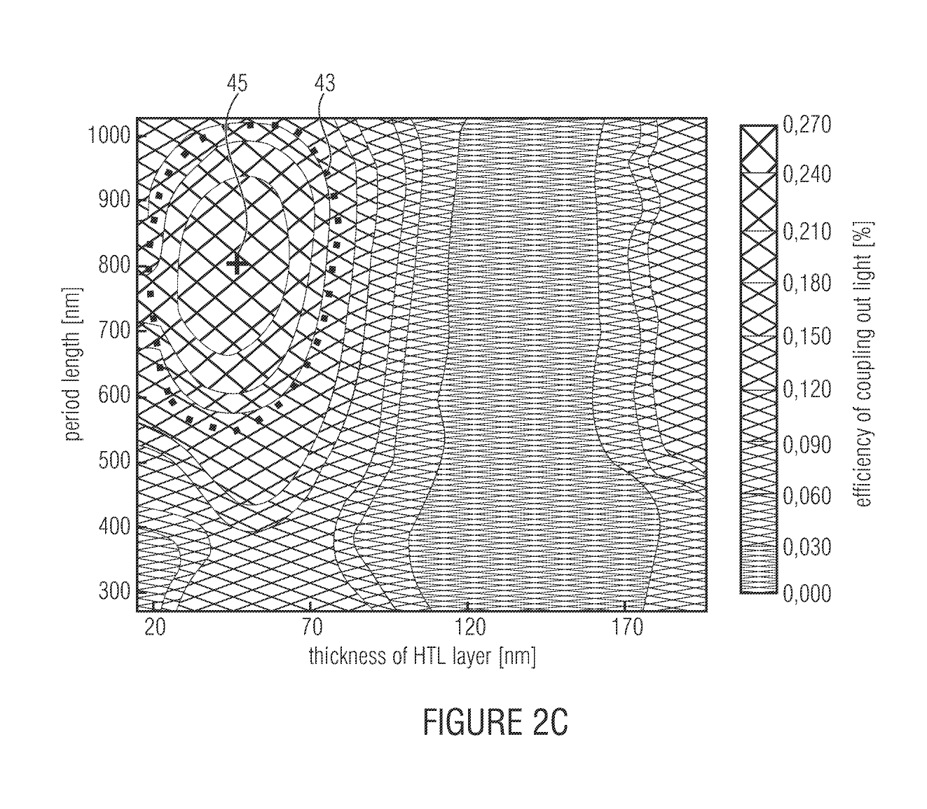

FIG. 2a shows another embodiment of a light emission device in which the organic light-emitting layer 16 is implemented as a layer stack. FIG. 2b illustrates the dependence of the efficiency of coupling out light on the layer thickness h₁₈ of the intermediate layer 18. FIG. 2c illustrates the dependence of the efficiency of coupling out light on the period length and layer thickness of one of the organic layers (HTL layer) of the layer stack.

FIG. 2a shows an exemplary embodiment of a phosphorescent light emission device (OLED) which is able to emit light at a green spectral portion. In this embodiment, the first electrode layer 12 which is referred to as anode comprises aluminum at a layer thickness of 200 nm (such as, for example, 180 to 240 nm). The second electrode layer 14 which is referred to as cathode comprises semi-transparent silver and exemplarily has a layer thickness of about 20 nm. The light-emitting layer 16 in this embodiment is realized by means of a layer stack including five individual layers. The first individual layer is a hole transport layer (HTL) 16a which comprises N′,N′-tetrakis-(4-methoxyphenyl)-benzidine (MeO-TPD) as a host and 2,3,5,6-tetrafluoro-7,7,8,8,-tetracyanoquinodimethane as a dopant. The second individual layer is an electron blocking layer (EBL) 16b and comprises 2,2′,7,7′-tetrakis-(N,N-diphenylamino)-9,9′-spirobifluorene (Spiro-TAD). The third individual layer is a double emitting layer (double EML) 16c which exemplarily comprises a layer thickness of 20 nm (such as, for example, 5 to 15 nm) and is implemented as a green phosphorescent emitter tris(2-phenylpyridine)-iridium [Ir(ppy)3], doped in a matrix of 4,4′,4″-tris(N-carbazolyl)-triphenylamine (TCTA) or 2,2′,2″-(1,3,5-benzenetriyl)-tris[1-phenyl-1>H-benzimidazole] (TPBI). The fourth individual layer is a hole blocking layer (HBL) 16d made of 4,7-diphenyl-1,10-phenanthroline (Bphen). The last individual layer of the organic layer 18 is an electron transport layer (ETL) 16e which comprises Bphen and cesium. The electron blocking layer 16b and the hole transport layer 16a exemplarily exhibit a layer thickness of 10 nm (such as, for example, 5 to 15 nm). The intermediate layer 18 exemplarily comprises two materials to form a linear optical lattice structure, namely doped amorphous silicon for first lattice sub-regions 18a and silicon oxide for second lattice sub-regions 18b.

The resulting mode of functioning of the light emission device illustrated in FIG. 2a basically corresponds to the mode of functioning illustrated in FIG. 1, wherein the light emission device illustrated is able to emit light at a green spectral portion. It is pointed out that light emission devices comprising other organic materials in the organic layers may emit other spectral portions. Different parameters which influence the efficiency of coupling out light will be discussed below. Generally, it is to be pointed out that the period length b₁₈ₐ+b_{18b} of the optical lattice structure depends on the wavelength of the light to be emitted and/or is selected correspondingly. Consequently, the period length is adjusted in regions to the wavelength of the light to be emitted such that the period length is in a range from 0.2 to 5.0 times the value of the wavelength. For light emission devices with the green spectral portion of light to be emitted according to this embodiment, a period length of the optical lattice structure of exemplarily 800 nm (such as, for example, 700 to 900 nm) is ideal. As regards layer thicknesses, a maximum coupling-out efficiency may exemplarily be achieved when a layer thickness of the ETL layer of 205 nm (such as, for example, 180 to 230 nm) is chosen and when the layer thickness of the HTL layer is correspondingly set to 40 nm (such as, for example, 30 to 65 nm).

The precise determination and/or optimization of the period length, layer thickness h₁₈ of the intermediate layer 18 and layer thickness of the HTL layer 16a parameters will be described referring to FIGS. 2a and 2b.

FIG. 2b exemplarily illustrates a diagram of an efficiency of coupling out light of the light emission device at the green spectral portion of light to be emitted in dependence on the layer thickness h₁₈ of the intermediate layer 18 using a graph 41 which has been determined by means of numerical simulation. A maximum efficiency of coupling out light is at a layer thickness h₁₈ of 60 nm (such as, for example, between 50 and 65 nm) and a minimum efficiency of coupling out light at a layer thickness h₁₈ of 20 nm. Consequently, in the embodiment shown in FIG. 2a, the layer thickness h₁₈ is determined to be 60 nm. The coupling-out efficiency of the embodiment described is 27%, which is an increase by 35% compared to the coupling-out efficiency of 20% of a configuration not containing an optical lattice structure. Generally, it is to be stated that the layer thickness h₁₈ of the intermediate layer 18, which typically has a value between 5 and 1000 nm, is dependent on the frequency of the light emitted and advantageously is constant in order for the optical characteristics to remain equal over the entire width of the optical lattice structure.

FIG. 2c exemplarily shows the result of the simulation of the efficiency of coupling out light when varying the period length in dependence of the layer thickness of the HTL layer 16a of the organic layer stack of the light emission device which is able to emit light at a green spectral portion. The period length here is indicated versus the layer thickness of the HTL layer 16a, wherein the different contour lines are to illustrate or represent the efficiency of coupling out light. It is to be recognized that the efficiency to couple out light is comparatively high in a region 43. The region 43 extends over a period length between 550 and 1000 nm and a layer thickness of the HTL layer 16a between 30 and 65 nm, wherein an absolute maximum (cf. marked region 45) is about at a period length of 800 nm and a layer thickness of 40 nm. Consequently, in the embodiment shown in FIG. 2a, the period length and layer thickness of the HTL layer 16a parameters, which are mutually dependent, are determined in correspondence with the maximum efficiency to couple out light (cf. marked region 45).

In accordance with another embodiment, the optical characteristics of the intermediate layer are adjusted via further parameters, which will be discussed below in greater detail. The different indices of refraction of the first and second lattice sub-regions 18a and 18b result from the different material characteristics and/or the different materials of the lattice sub-regions 18a and 18b. The indices of refraction of the lattice sub-regions 18a and 18b are mutually dependent, dependent on the indices of refraction of further layers of the light emission device, and dependent on the wavelength of the light to be emitted. The materials or material characteristics of the first and/or second lattice sub-region(s) 18a and/or 18b may advantageously differ from the material or material characteristics of the first electrode layer 12 so as to form interfaces of different indices of refraction between the first electrode layer 12 and the first or second lattice sub-regions 18a and/or 18b and thus adjust the optical characteristics. Another parameter influencing the optical characteristics of the intermediate layer 18 is the absorption length of the lattice sub-regions which is also adjusted in dependence on the wavelength of the light to be emitted such that the absorption length at the wavelength emitted of the light is at least 50 nm. Of further influence on the coupling-out efficiency is the optical lattice structure itself which may exemplarily correspond to an oblique-angled, rectangular, rectangular-centered, hexagonal or squared Bravais lattice or a quasi-crystal to couple out the light modes bound efficiently and angle-truly.

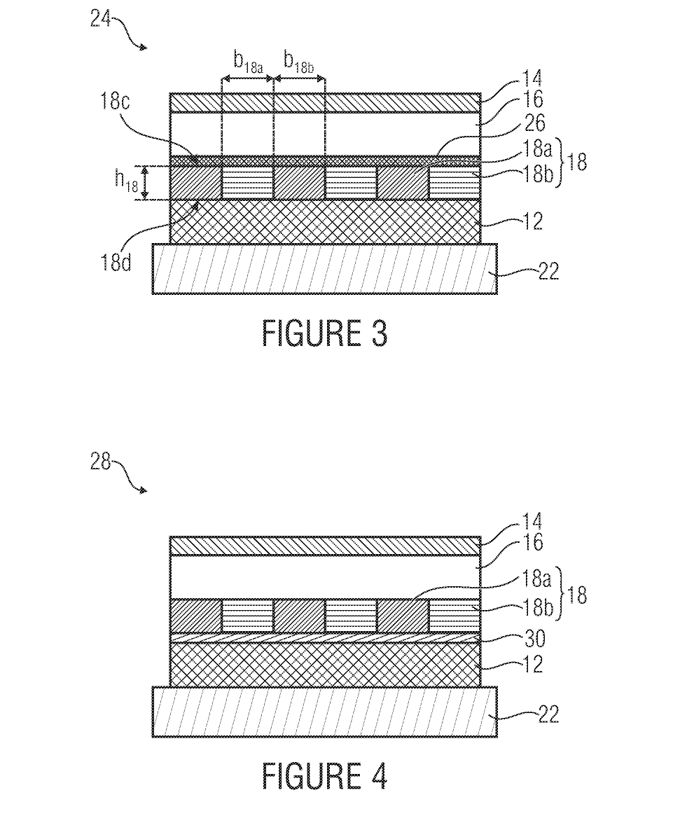

FIG. 3 shows a light emission device 24 in accordance with another embodiment. The light emission device 24, when compared to the light emission device 1, comprises an additional (optional) lateral charge transport layer 26 made of a conductive material which is arranged between the intermediate layer 18 and the light-emitting layer 16. The lateral transport layer 26 is applied onto the first planar main surface 18c of the intermediate layer 18 and, as does the intermediate layer 18, comprises a planar main surface associated to the light-emitting layer 16.

With regard to functionality, the light emission device 24 corresponds basically to the light emission device 1 of FIG. 1. The lateral charge transport layer 26 is applied onto the planar first main surface 18c of the intermediate layer 18 and serves to ensure a current to flow as constant as possible over the area or the most homogeneous current density distribution possible between the first and second electrode layers 12 and 14 through the organic light-emitting layer 16 over the entire active width of the organic layer 16 or a pixel or sub-pixel of the organic layer 16. The purpose behind this is eliminating effects which arise due to the fact that the intermediate layer 18 is conductive only in regions, such as, for example, in one of the first or second lattice sub-regions 18a or 18b. Effects of this kind occur particularly in lattice structures of large period lengths. The typical charge transport lengths correspond to the lateral widths b₁₈ₐ and b_{18b} of the lattice sub-regions 18a and 18b. These are usually much smaller than the active width of the organic layer which determines the charge transport lengths of the electrode layer 12. Thus, lower a conductivity is sufficient for the lateral charge transport layer 26, when compared to the electrode layer 12. The lateral charge transport layer 26 is made of a thin conductive, advantageously transparent material, such as, for example, amorphous silicon. Alternatively, other conductive materials, such as, for example, indium tin oxide or another transparent conductive oxide, advantageously of high absorption lengths, may be used.

FIG. 4 shows a light emission device 28 in accordance with another embodiment which, when compared to the light emission device 1 of FIG. 1, additionally comprises an (optional) distance layer 30 between the intermediate layer 18 and the first electrode layer 12. Basically, the functionality of the light emission device 28 corresponds to that of the light emission device 1.

The distance layer 30 serves for optimizing the position of the intermediate layer 18 within the resonator, i.e. within the layer arrangement of the electrode layers 12 and 14. The layer thickness of the distance layer 30 is adjusted for optimization purposes. The distance layer 30 differs from the electrode layer 12 with regard to its conductivity. The distance layer 30 only serves for a vertical current transport, but not the lateral distribution of charge carriers over the entire active area such that lower a conductivity is sufficient when compared to the electrode layer 12. The distance layer 30 may exemplarily be made of a doped semiconductor such as, for example, amorphous silicon, or a transparent and conductive metal oxide (TCO) and may advantageously comprise a long absorption length.

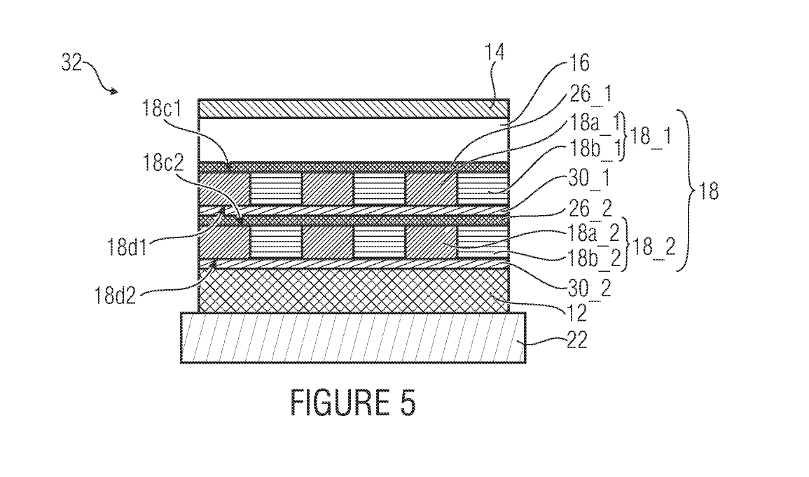

FIG. 5 shows a light emission device 32 in accordance with another embodiment in which the intermediate layer, including the lattice structures, is formed as an intermediate layer stack 18 which comprises two intermediate layers 18_1 and 18_2. The two intermediate layers 18_1 and 18_2 each comprise an optical lattice structure. The layer stack may further comprise lateral charge transport layers 26_1 and 26_2 and distance layers 30_1 and 30_2. The light emission device 32 includes the substrate 13 on which the first electrode layer 12 is arranged. The light-emitting layer 16 is arranged between the first electrode layer 12 and the second electrode layer 14. The two intermediate layers 18_1 and 18_2 are located between this light-emitting layer 16 and the first electrode layer 12. The first intermediate layer 18_1 arranged closer to the light-emitting layer 16 comprises first lattice sub-regions 18a_1 and second lattice sub-region 18b_1 of the optical lattice structure. A lateral charge transport layer 26_1 on a first main surface 18c_1 facing the light-emitting layer 16 is arranged between the intermediate layer 18_1 and the light-emitting layer 16. A distance layer 30_1 is provided on a second main surface 18d_1 facing the first electrode layer 12. The second intermediate layer 18_2 arranged closer to the first electrode layer 12 in analogy comprises first lattice sub-regions 18a_2 and second lattice sub-regions 18b_2. In analogy to the intermediate layer 18_1, another lateral charge transport layer 26_2 is provided on a first main surface 18c_2, facing the light-emitting layer 16 of the intermediate layer 18_2 and another distance layer 30_2 provided on the second main surface 18d_2 facing the first electrode layer 12.

With regard to functionality, the light emission device 32 corresponds to the embodiments mentioned before, wherein the additional intermediate layer 18_2, including its optical lattice structure, is arranged to be parallel to the intermediate layer 18_1 to superpose the effects of several optical lattice structures. Consequently, the intermediate layer 18_2 may, when compared to the intermediate layer 18_1, comprise different lattice characteristics, such as, for example, a different period length. Here, on the one hand, coupling out may be optimized for several colors and, on the other hand, at the same time light may be allowed to specifically couple out in several directions. In analogy to the embodiments mentioned before, the (optional) lateral charge transport layers 18_1 and 18_2 serve ensuring the lateral transport of charge carriers over the width b₁₈ of the non-conducting lattice sub-regions 18a_1 or 18b_1 and 18a_2 or 18b_2, respectively. Also in analogy to the embodiments mentioned before, the (optional) distance layers 30_1 and 30_2 serve optimizing the position of the intermediate layers 18_1 and 18_2 in the layer arrangement.

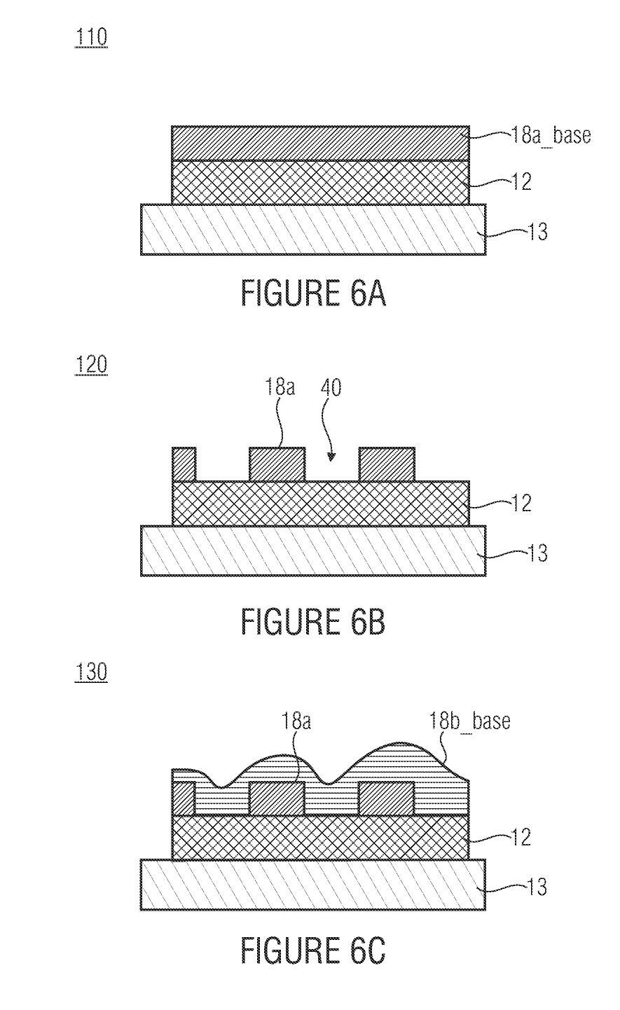

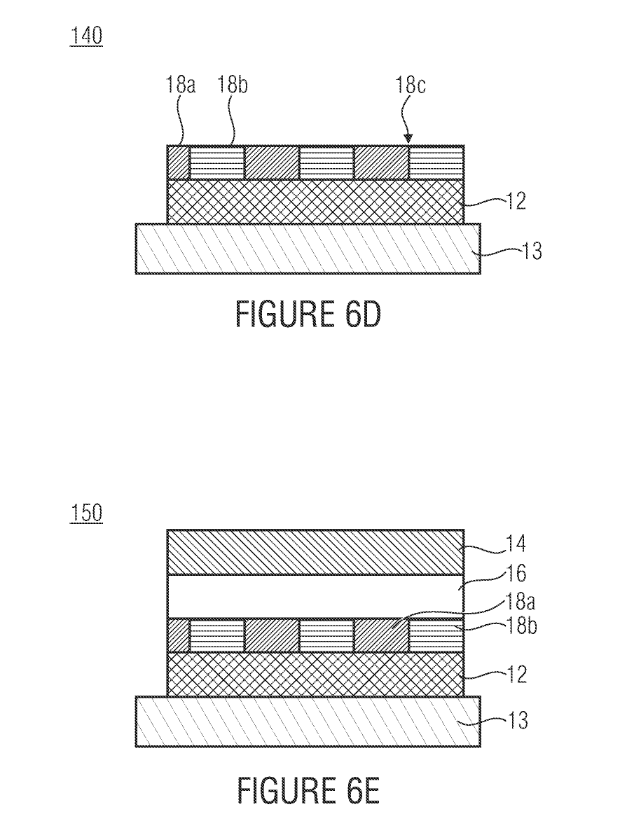

An exemplary method 100 of manufacturing the electroluminescent light emission device 1 in accordance with an embodiment of the present invention will be described below using a basic process sequence of FIG. 6a to FIG. 6e. In addition, it is pointed out that, when referring to FIGS. 6a to 6d, the step of generating a planarized intermediate layer 18 is illustrated in detail.

FIG. 6a shows the initial state of the method 100 for manufacturing the light emission device 1. In a first method step 110, the substrate 13 is provided and the first electrode layer 12 is applied thereon. Furthermore, a first lattice structure base layer 18a_base is applied onto the electrode layer 12, from which subsequently first lattice sub-regions 18a are formed. Applying or depositing the first lattice structure base layer 18_base onto the electrode layer 12 may exemplarily take place by means of chemical vapor deposition (CVD) of an SiO₂ layer.

FIG. 6b illustrates the subsequent step 120 of patterning the first lattice structure base layer 18a_base. What is illustrated is the already patterned lattice structure base layer such that same forms the first spaced-apart lattice sub-regions 18a, and exposed intermediate regions 40. In the step illustrated, the lattice structure base layer 18a_base or SiO₂ layer is patterned so as to obtain first spaced-apart lattice sub-regions 18a and exposed intermediate regions 40. Here, the SiO₂ layer may exemplarily be covered with a photo resist which is subsequently patterned by photolithographic processes. This pattern may then be transferred to the SiO₂ layer by means of reactive ion etching (RIE).

FIG. 6c illustrates step 130 of applying a second lattice structure base layer 18b_base onto the first spaced-apart lattice sub-regions 18a and the exposed intermediate regions 40. Here, a second lattice structure base layer 18b_base, exemplarily made of doped amorphous silicon (a-Si), is applied onto the first spaced-apart lattice sub-regions 18a and the exposed intermediate regions 40, exemplarily by means of chemical vapor deposition.

FIG. 6d illustrates the next step 140 of planarizing the second lattice structure base layer 18b_base, the result being second lattice sub-regions 18b. Subsequently, at least the second lattice structure base layer is planarized so as to obtain the planarized intermediate layer including the optical lattice structure. Here, the second lattice structure base layer 18b_base is polished back to the first (grown) lattice sub-regions 18a by means of a chemical-mechanical planarization process (CMP). The process selectivity relative to SiO₂ and a-Si allows stopping on the first lattice sub-regions 18a. The layer thickness h₁₈ and, thus, the lattice height may be controlled by this such that the first lattice sub-regions 18a are partly eroded in the planarization process. The resulting planarity of the first main surface 18c is process-dependent.

FIG. 6e shows the final step of the method for manufacturing so as to illustrate the last steps 150 of applying the light-emitting layer 16 and the second electrode layer 14. After generating the intermediate layer 18, the light-emitting layer 16 which exemplarily may comprise several individual layers is arranged on the intermediate layer 18, before the second electrode layer 14 is applied onto the light-emitting layer 16.

In accordance with further embodiments, the method of manufacturing described above may comprise the step of arranging the lateral charge transport layer 26, after the step of generating the planarized intermediate layer 18 and/or after the step of planarizing the intermediate layer 18 (before the step of arranging the light-emitting layer 16 on the intermediate layer 18). Also, the method for manufacturing may include the step of arranging the distance layer 30 on the electrode 12, before generating the intermediate layer 18. Furthermore, in analogy to the method described before, a light emission device 32 in correspondence with the embodiment shown in FIG. 5 may be manufactured, wherein the step of generating the intermediate layer is performed for the intermediate layer 18_1 and again for the intermediate layer 18_2.

In accordance with another embodiment, the layer arrangement may be subdivided into pixels and/or sub-pixels. Subdividing pixels allows using the light emission device as a display. By subdividing pixels into sub-pixels which exemplarily each may represent one of the three primary colors, it is possible for the pixels to represent different colors by mixing the three primary colors at different intensities. The light emission device may be driven either actively or passively in order to drive the pixels or sub-pixels selectively. With active driving, an integrated circuit which drives the pixels selectively and makes available the current supply for these is arranged on the substrate. With passive driving, the light emission device including several pixels is driven using a matrix and supplied with a current from outside. With the passive form, an integrated circuit for driving the pixels may also be arranged on the same substrate next to the light emission device or externally.

Alternatively, the layer arrangement of the light emission device may comprise further light-emitting layers. This exemplarily allows realizing different color representations in one region, for example when three light-emitting layers of different colors are arranged one above the other.

Referring to the embodiments of FIG. 2 and FIG. 3, it is pointed out that, in another embodiment, a light emission device may comprise both the lateral transport layer 26 and the distance layer 30.

In another alternative embodiment, the intermediate layer 18 may comprise further lattice sub-regions, apart from the first and second lattice sub-regions, including further indices of refraction.

Referring to FIG. 5, the light emission device 32 may comprise an intermediate layer stack 18 comprising further intermediate layers 18_1, 18_2, 18_3, . . . and 18_{—}n.

It is pointed out that the embodiments described of the light emission device may, depending on the material characteristics of the substrate 13 and the electrode layers 12 and 14, be employed both as top-emitting OLED (TOLED) and as bottom-emitting OLED (BOLED) and as transparent OLED. Exemplarily, for TOLEDs, in contrast to BOLEDs, an opaque substrate 13, a reflecting electrode layer 12 and a transparent electrode layer 14 are used.

Referring to the embodiments illustrated before, it is pointed out that the setup of the light emission device may be over an area and/or subdivided in pixels and/or sub-pixels and that consequently light emitted may be radiated over an area and/or in pixels or sub-pixels.

In accordance with an embodiment, a light emission device is provided which comprises a substrate and a layer arrangement applied onto the substrate comprising a first electrode layer made of a conductive material, a second electrode layer made of a conductive material, at least one light-emitting layer made of an organic material arranged between the first electrode layer and the second electrode layer, and at least one intermediate layer comprising an optical lattice structure arranged between the light-emitting layer and one of the two electrode layers, a first main surface of the intermediate layer facing the light-emitting layer and the first main surface of the intermediate layer being formed to be planar within a tolerance range at least in the region of the optical lattice structure, and the intermediate layer being conductive at least in regions between the first main surface and a second main surface thereof.

The tolerance range here allows evenness of the first main surface in a range of less than +/−50 nm.

The optical lattice structure includes first and second lattice sub-regions which comprise different materials and/or different material characteristics at different indices of refraction, wherein the period length of the optical lattice structure is adjusted, at least in regions, to a wavelength of the light to be emitted by the light-emitting layer, and the period length of the lattice structure of the intermediate layer is in a range of 0.2 to 5.0 times the wavelength of the light to be emitted by the light-emitting layer, the first and second lattice sub-regions exhibiting an absorption length of at least 50 nm at the wavelength of the light to be emitted by the light-emitting layer.

Additionally, the layer arrangement comprises a conductive charge transport layer between the light-emitting layer and the intermediate layer.

In addition, the layer arrangement additionally comprises a homogenous, conductive distance layer between the intermediate layer and one of the electrode layers.

Here, the optical lattice structure of the intermediate layer corresponds to an oblique-angled, rectangular, rectangular-centered, hexagonal or squared Bravais lattice and is formed to be a quasi-crystal.

The layer thickness of the intermediate layer is constant within another tolerance range and smaller than 1000 nm.

The layer arrangement is subdivided into pixels and/or sub-pixels which may be driven selectively, passively or actively by means of an integrated circuit.

The intermediate layer and the first and second electrode layers here comprise different conductive materials.

Here, the layer arrangement comprises another intermediate layer including another optical lattice structure arranged between the first intermediate layer and the second electrode layer, a first main surface of the further intermediate layer facing the light-emitting layer and the first main surface of the further intermediate layer being formed to be planar within a tolerance range at least in the region of the optical lattice structure, and the further intermediate layer being conductive at least in regions between the first main surface and a second main surface thereof.

In accordance with another embodiment, a method for manufacturing a light emission device including a layer arrangement comprises providing a substrate, arranging a first electrode layer on the substrate, generating a planarized intermediate layer comprising an optical lattice structure on the electrode layer, the planarized intermediate layer being conductive at least in regions between a first and a second main surface thereof, arranging a light-emitting layer on the intermediate layer, and arranging a second electrode layer on the light-emitting layer.

Thus, the step of generating the intermediate layer comprises applying a first lattice structure base layer on the electrode layer, patterning the first lattice structure base layer so as to obtain first spaced-apart lattice sub-regions and exposed intermediate regions, applying a second lattice structure base layer on the first spaced-apart lattice sub-regions and the exposed intermediate regions; and planarizing at least the second lattice structure base layer so as to obtain the planarized intermediate layer including the optical lattice structure, and generating another planarized intermediate layer including another optical lattice structure on the planarized intermediate layer, the planarized further intermediate layer being conductive at least in regions between a first and a second main surface thereof.

While this invention has been described in terms of several embodiments, there are alterations, permutations, and equivalents which will be apparent to others skilled in the art and which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

### REFERENCES

[1] C. Adachi, M. A. Baldo, S. R. Forrest, and M. E. Thompson, “Nearly 100% internal phosphorescence efficiency in an organic light-emitting device”, J. Appl. Phys. 90, 5048 (2001)
[2] S. Möller and S. R. Forrest, “Improved light out-coupling in organic light emitting diodes employing ordered microlens arrays”, J. Appl. Phys. 81, 3324 (2002)
[3] J. Zhou, N. Ai, L. Wang, H. Zheng, C. Luo, Z. Jiang, S. Yu, Y. Cao and J. Wang, “Roughening the white OLED substrate's surface through sandblasting to improve the external quantum efficiency”, Org. Electronics 12, 648-(2011)
[4] T. Yamasaki, K. Sumioka, and T. Tsutsui, “Organic light-emitting device with an ordered monolayer of silica microspheres as a scattering medium”, Appl. Phys. Lett. 76, 1243 (2000)
[5] T. Tsuitsui, M. Yahiro, H. Yokogawa, K. Kawano, Y. Yokoyama, “Doubling Coupling-Out Efficiency in Organic Light-Emitting Devices Using a Thin Silica Aerogel Layer”, Adv. Mater. 13, 2174 (2001)
[6] Y. R. Do, Y.-C. Kim, Y.-W. Song, S.-H. Lee, “Enhanced light extraction efficiency from organic light emitting diodes by insertion of a two-dimensional photonic crystal structure”, J. Appl. Phys. 96, 7629 (2004)
[7] B. J. Matterson, J. M. Lupton, A. F. Safonov, M. G. Salt, W. L. Barnes, I. D. W. Samuel, “Increased Efficiency and Controlled Light Output from Microstructured Light-Emitting Diode”, Adv. Mat. 13, 2 (2001)
[8] M. Fujita, K. Ishihara, T. Ueno, T. Asano, S. Noda, H. Ohata, T. Tsuji, H. Nakada, N. Shimoji, “Optical and Electrical Characteristics of Organic Light-Emitting Diodes with Two-Dimensional Photonic Crystals in Organic/Electrode Layers”, Jap. J. of Appl. Phys. 44, 6A (2005)
[9] U. Geyer, J. Hauss, B. Riedel, S. Gleiss, U. Lemmer, M. Gerken, “Large-scale patterning of indium tin oxide electrodes for guided mode extraction from organic light-emitting diodes”, J. Appl. Phys. 104, 093111 (2008)
[10] J. Feng, T. Okamoto, R. Naraoka, S. Kawata, “Enhancement of surface plasmon-mediated radiative energy transfer through a corrugated metal cathode in organic light-emitting devices”, Appl. Phys. Lett. 93, 061106 (2008)
[11] G. Garcia-Belmonte, J. M. Montero, Y. Ayyad-Limonge, E. M: Barea, J. Bisquert, H. J. Bolink, “Perimeter leakage current in polymer light emitting diodes”, Curr. Appl. Phys. 9, 414 (2009)

1. A light emission device comprising:
a substrate; and
a layer arrangement applied onto the substrate comprising a first electrode layer made of a conductive material, a second electrode layer made of a conductive material, at least one light-emitting layer made of an organic material arranged between the first electrode layer and the second electrode layer and formed as an organic layer stack, and at least one intermediate layer comprising an optical lattice structure arranged between the organic layer stack and one of the two electrode layers,
wherein a first main surface of the intermediate layer faces the organic layer stack and the first main surface of the intermediate layer is formed to be planar within a tolerance range at least in the region of the optical lattice structure, and the intermediate layer is conductive at least in regions between the first main surface and a second main surface, and
wherein the intermediate layer comprises the first and second lattice sub-regions, and the lattice sub-regions comprise a constant layer thickness.

2. The light emission device in accordance with claim 1, wherein the tolerance range represents unevenness of the first main surface in a range of less than +/−50 nm.

3. The light emission device in accordance with claim 1, wherein the first and second lattice sub-regions comprise different materials and/or different material characteristics at different indices of refraction, and wherein the period length of the optical lattice structure is adjusted at least in regions to a wavelength of the light to be emitted by the light-emitting layer.

4. The light emission device in accordance with claim 1, wherein the period length of the lattice structure of the intermediate layer is in a range of 0.2 to 5.0 times the wavelength of the light to be emitted by the light-emitting layer.

5. The light emission device in accordance with claim 2, wherein the first and second lattice sub-regions comprise an absorption length of at least 50 nm at the wavelength of the light to be emitted by the light-emitting layer.

6. The light emission device in accordance with claim 1, wherein the layer arrangement additionally comprises a conductive charge transport layer between the light-emitting layer and the intermediate layer.

7. The light emission device in accordance with claim 1, wherein the layer arrangement additionally comprises a homogeneous conductive distance layer between the intermediate layer and one of the electrode layers.

8. The light emission device in accordance with claim 1, wherein the optical lattice structure of the intermediate layer corresponds to an oblique-angled, rectangular, rectangular-centered, hexagonal or squared Bravais lattice or is formed as a quasi-crystal.

9. The light emission device in accordance with claim 1, wherein the layer thickness of the intermediate layer is constant within another tolerance range and smaller than 1000 nm.

10. The light emission device in accordance with claim 1, wherein the layer arrangement is subdivided into pixels and/or sub-pixels which may be driven selectively, passively or actively by means of an integrated circuit.

11. The light emission device in accordance with claim 1, wherein the intermediate layer and the first and second electrode layers comprise different conductive materials.

12. The light emission device in accordance with claim 1, wherein the layer arrangement comprises another intermediate layer comprising another optical lattice structure arranged between the first intermediate layer and the first electrode layer, a first main surface of the further intermediate layer facing the light-emitting layer and the first main surface of the further intermediate layer being formed to be planar within a tolerance range at least in the region of the optical lattice structure, and the further intermediate layer being conductive at least in regions between the first main surface and a second main surface.

13. The light emission device in accordance with claim 1, wherein the organic layer stack comprises a hole transport layer, an electron blocking layer, a double emitter layer, a hole blocking layer and/or an electron transport layer.

14. The light emission device in accordance with claim 1, wherein the intermediate layer comprises a silicon material, amorphous silicon material, silicon oxide material and/or metal oxide.

15. A method for manufacturing a light emission device comprising a layer arrangement, comprising:
providing a substrate;
arranging a first electrode layer on the substrate;
generating a planarized intermediate layer comprising an optical lattice structure on the electrode layer, the planarized intermediate layer being conductive at least in regions between a first and a second main surface;
arranging a light-emitting layer on the intermediate layer; and
arranging a second electrode layer on the light-emitting layer,
wherein generating the intermediate layer comprises:
applying a first lattice structure base layer on the electrode layer;
patterning the first lattice structure base layer so as to achieve first spaced-apart lattice sub-regions and exposed intermediate regions;
applying a second lattice structure base layer on the first spaced-apart lattice sub-regions and the exposed intermediate regions; and
planarizing at least the second lattice structure base layer so as to achieve the planarized intermediate layer comprising the optical lattice structure.

16. The method in accordance with claim 15, further comprising:
generating another planarized intermediate layer comprising another optical lattice structure on the planarized intermediate layer, the further planarized intermediate layer being conductive at least in regions between a first and a second main surface thereof.

17. A light emission device comprising:
a substrate; and
a layer arrangement applied onto the substrate comprising a first electrode layer made of a conductive material, a second electrode layer made of a conductive material, at least one light-emitting layer made of an organic material arranged between the first electrode layer and the second electrode layer and formed as an organic layer stack, and at least one intermediate layer comprising an optical lattice structure arranged between the organic layer stack and one of the two electrode layers,
wherein a first main surface of the intermediate layer faces the organic layer stack and the first main surface of the intermediate layer is formed to be planar within a tolerance range at least in the region of the optical lattice structure, and the intermediate layer is conductive at least in regions between the first main surface and a second main surface,
wherein the intermediate layer comprises the first and second lattice sub-regions, and the lattice sub-regions comprise a constant layer thickness, and
wherein the organic layer stack comprises a hole transport layer, an electron blocking layer, a double emitter layer, a hole blocking layer and/or an electron transport layer.

18. A light emission device comprising:
a substrate; and
a layer arrangement applied onto the substrate comprising a first electrode layer made of a conductive material, a second electrode layer made of a conductive material, at least one light-emitting layer made of an organic material arranged between the first electrode layer and the second electrode layer and formed as an organic layer stack, and at least one intermediate layer comprising an optical lattice structure arranged between the organic layer stack and one of the two electrode layers,
wherein a first main surface of the intermediate layer faces the organic layer stack and the first main surface of the intermediate layer is formed to be planar within a tolerance range at least in the region of the optical lattice structure, and the intermediate layer is conductive at least in regions between the first main surface and a second main surface,
wherein the intermediate layer comprises the first and second lattice sub-regions, and the lattice sub-regions comprise a constant layer thickness, and
wherein the intermediate layer comprises a silicon material, amorphous silicon material, silicon oxide material and/or metal oxide.
